(19) United States
(12) Patent Application Publication
(10) Pub. No.: US 2011/0311737 A1
(43) Pub. Date: Dec. 22, 2011

(54) VAPOR DEPOSITION APPARATUS FOR MINUTE-STRUCTURE AND METHOD THEREFOR

(75) Inventors: Yukichi Shigeta, Kanagawa (JP); Kunihiko Aoyagi, Kanagawa (JP); Hiroyuki Nose, Tokyo (JP)

(73) Assignee: IHI CORPORATION, Tokyo (JP)

(21) Appl. No.: 13/148,640

(22) PCT Filed: Feb. 4, 2010
(86) PCT No.: PCT/JP2010/051599

§ 371 Date: Aug. 9, 2011

(30) Foreign Application Priority Data
Feb. 9, 2009 (JP) 2009-026928

(51) Int. Cl. C23C 16/50; B82Y 40/00; B82Y 30/00

(52) U.S. Cl. 427/585; 118/723 VE; 977/742; 977/891; 977/932

(57) ABSTRACT

A vapor deposition apparatus for a minute-structure includes a surface acoustic wave device 10 that has at least a pair of electrodes 12 and 13 arranged at an interval on a surface of a piezoelectric body 11, a vacuum vapor deposition device 20 that vacuum-deposits at least two substances A and B on a surface of the surface acoustic wave device, and a high-frequency application device 30 that applies a high-frequency voltage between the electrodes of the surface acoustic wave device. In the state where a standing wave of surface acoustic waves is generated on the surface of the surface acoustic wave device by applying the high-frequency voltage, a plurality of thin film layers are formed, and a minute-structure is vapor-deposited at a specific position of the standing wave.

### BACKGROUND OF THE INVENTION

1. Technical Field of the Invention

The present invention relates to a vapor deposition apparatus for forming a minute-structure at a predetermined position and a method therefor.

2. Description of the Related Art

Fullerene (C₆₀) is one of isotopes of carbons, and has a closed polyhedron structure where the skeleton of carbon atoms constituting a molecule is made up of combinations of regular pentagons and regular hexagons. Functional molecules including such fullerene as well as carbon nanotube are known to have various functions.

However, since a molecular size of the functional molecules or the like is very small (in the case of fullerene, about 1 nm in diameter), it is very difficult to control a position thereof precisely. Therefore, as position control means that forms such a minute-structure at a predetermined position, the applicant of the present invention has created the device of Patent Document 1, and has filed the application therefor.

Other position control means are disclosed in Patent Documents 2 and 3.

Patent Document 1 has an object of controlling a position of a minute-structure and a relative position between elements forming a minute-structure precisely. As schematically illustrated in FIG. 1, a standing wave 2 of surface acoustic waves is generated on a surface of a substrate 1 so that the standing wave enables setting of a position at which a material (quantum dot 3) of a minute-structure is adhered, i.e., a position of the minute-structure. In this drawing, reference numeral 4 denotes an electrode.

[Patent Document 1]
Japanese Patent Publication No. 2006-332227, “method and apparatus for manufacturing minute-structure substance”

[Patent Document 2]
Japanese Patent Publication No. 2008-260073, “method for aligning minute-structures and substrate having aligned minute-structures, as well as integrated circuit apparatus and display element”

[Patent Document 3]
Japanese Patent No. 4192237, “shape control method of nano structure”

### SUMMARY OF THE INVENTION

The method and apparatus disclosed in Patent Document 1 have the following problems:

(1) a position of a formed minute-structure depends to a large degree on a surface state of a substrate; and

(2) transmission efficiency of high frequency waves to a substrate is low in a vacuum because of large reflections of high-frequency waves to a power source.

The present invention has been created to cope with the above-stated problems. That is, it is an object of the present invention to provide a vapor deposition apparatus for a minute-structure and a method therefor, by which a minute-structure can be formed at a predetermined position while reducing influences of a surface state of a substrate, and high-frequency waves can be transmitted to the substrate efficiently.

According to the present invention, there is provided a vapor deposition apparatus for a minute-structure, comprising:

a surface acoustic wave device including at least a pair of electrodes arranged at an interval on a surface of a piezoelectric body;

a vacuum vapor deposition device that vacuum-deposits at least two substances on a surface of the surface acoustic wave device; and

a high-frequency application device that applies a high-frequency voltage between the electrodes of the surface acoustic wave device,

wherein in a state where a standing wave of surface acoustic waves is generated on the surface of the surface acoustic wave device by applying the high-frequency voltage, a plurality of thin film layers are formed, and a minute-structure is vapor-deposited at a specific position of the standing wave.

According to a preferable embodiment of the present invention, a fullerene layer is vapor-deposited on an entire surface of the surface acoustic wave device to form the plurality of thin film layers, and then, the minute-structure is vapor-deposited at the specific position of the standing wave.

The vacuum vapor deposition device includes a vacuum chamber that accommodates the surface acoustic wave device therein and reduces a pressure therein to a predetermined degree of vacuum, and a vacuum connector that introduces high-frequency current into the vacuum chamber, and

the high-frequency application device includes:

a high-frequency generator that generates a high-frequency voltage at a predetermined frequency;

a device holder that includes an input conductive film and a grounded conductive film with impedance matched therebetween, and that inputs a high-frequency voltage to the surface acoustic wave device; and

a coaxial cable that includes a center conductor and shield metal with impedance matched therebetween, and that conveys a high-frequency voltage from the high-frequency generator to the device holder via the vacuum connector.

Preferably, the input conductive film and the grounded conductive film are plated on an insulating substrate via a NiCr thin film and an Au thin film,

and each of the input conductive film and the grounded conductive film is a Cu film with a thickness sufficiently larger than a skin depth by which the high frequency current can penetrate from a surface to an inside thereof.

According to the present invention, there is provided a method for vapor-depositing a minute-structure, comprising the steps of:

placing a surface acoustic wave device in a vacuum chamber, and reducing a pressure of the vacuum chamber to a predetermined degree of vacuum, the surface acoustic wave device including at least a pair of electrodes arranged at an interval on a surface of a piezoelectric body;

applying a high-frequency voltage between the electrodes to generate a standing wave of surface acoustic waves on a surface of the surface acoustic wave device; and

in this state, forming a plurality of thin film layers on the surface acoustic wave device, and vapor-depositing a minute-structure at a specific position of the standing wave.

According to a preferable embodiment of the present invention, a fullerene layer is vapor-deposited on an entire surface of the surface acoustic wave device to form the plurality of thin film layers, and then, the minute-structure is vapor-deposited at the specific position of the standing wave.

The fullerene layer is vapor-deposited at a substrate temperature ranging from a room temperature to 200° C., at a vapor-deposition rate of 0.6 to 1.7 \acute{Å}/min to obtain a vapor-deposition thickness of 30 \acute{Å} to 10 nm.

Preferably, the surface acoustic wave device is a SAW device that has the adjacent electrodes arranged at an interval ranging from 500 to 900 nm, and has a center frequency ranging from 850 to 900 MHz.

Preferably, the minute-structure is vapor-deposited at a position corresponding to a node of the standing wave while sequentially changing the standing wave of surface acoustic waves to a higher-order mode by sequentially increasing a frequency of the high-frequency voltage.

According to the above-stated apparatus and method of the present invention, the apparatus includes a surface acoustic wave device, a vacuum vapor deposition device, and a high-frequency application device. A surface acoustic wave device that has at least a pair of electrodes having an interval therebetween on a surface of a piezoelectric body is placed in a vacuum chamber, and a pressure of the vacuum chamber is reduced to a predetermined degree of vacuum. A high-frequency voltage is then applied between the electrodes to generate a standing wave of surface acoustic waves on the surface of the surface acoustic wave device. In this state, a plurality of thin-film layers are formed, and as a result, a homogeneous thin-film layer can be formed on the entire surface.

Especially, in this state, fullerene is vapor-deposited on the entire surface of the surface acoustic wave device to increase a diffusion length of fullerene so as to uniformly disperse a cluster of fullerene. Thereby, a homogeneous fullerene layer can be formed on the entire surface.

Since fullerene (C₆₀) is a functional molecule, and fullerene molecules are Van der Waals bonded with each other, a large diffusion length can be obtained by adsorbing several layers of fullerene on a piezoelectric substrate.

Accordingly, a high-frequency voltage is subsequently applied between the electrodes to generate a standing wave of surface acoustic waves on the surface of the surface acoustic wave device, and in this state, a minute-structure (e.g., Ag) is vapor-deposited on the fullerene layer. Thereby, a minute-structure can be vapor-deposited at a specific position (e.g., at a node) of the standing wave generated by the high-frequency voltage.

As a result, a minute-structure can be formed at a predetermined position while reducing influence of a surface state of the substrate (surface acoustic wave device).

The apparatus further includes a device holder that has an input conductive film and a grounded conductive film with impedance matched therebetween and that inputs a high-frequency voltage to the surface acoustic wave device, and a coaxial cable that has a center conductor and shield metal with impedance matched therebetween and that conveys a high-frequency voltage from the high-frequency generator to the device holder via the vacuum connector. Therefore, reflections of high-frequency waves to a power source can be minimized in the device holder and the coaxial cable, so that high-frequency waves can be efficiently transmitted to the substrate (surface acoustic wave device).

### BRIEF DESCRIPTION OF THE DRAWINGS

FIG. 1 schematically illustrates a method for manufacturing a minute-structure in Patent Document 1.

FIG. 2 explains Chladni figures.

FIG. 3 schematically illustrates an inter digital transducer (IDT).

FIG. 4 illustrates the entire configuration of a vapor deposition apparatus for minute-structure according to the present invention.

FIG. 5 illustrates the circuit configuration of a surface acoustic wave device used in an experiments.

FIG. 6 is a plan view of a device holder.

FIG. 7 is a connecting diagram between a device holder and a surface acoustic wave device.

FIG. 8 illustrates an SEM image of the substrate surface obtained from an experiment.

FIG. 9A illustrates an SEM image of a substrate surface when fullerene is vapor deposited on the substrate while applying a high-frequency voltage to the substrate.

FIG. 9B illustrates an SEM image of the substrate surface at a different area from FIG. 9A when fullerene is vapor deposited on the substrate while applying a high-frequency voltage to the substrate.

FIG. 10A illustrates an SEM image of a substrate surface obtained by using the substrate illustrated in FIG. 9A and FIG. 9B, applying a high-frequency voltage between electrodes so as to generate a standing wave of surface acoustic waves on the surface of a surface acoustic wave, and depositing Ag on the fullerene layer in this state.

FIG. 10B illustrates an SEM image of a substrate surface at a different area from FIG. 10A obtained by using the substrate illustrated in FIG. 9A and FIG. 9B, applying a high-frequency voltage across electrodes so as to generate a standing wave of surface acoustic waves on the surface of a surface acoustic wave, and depositing Ag on the fullerene layer in this state.

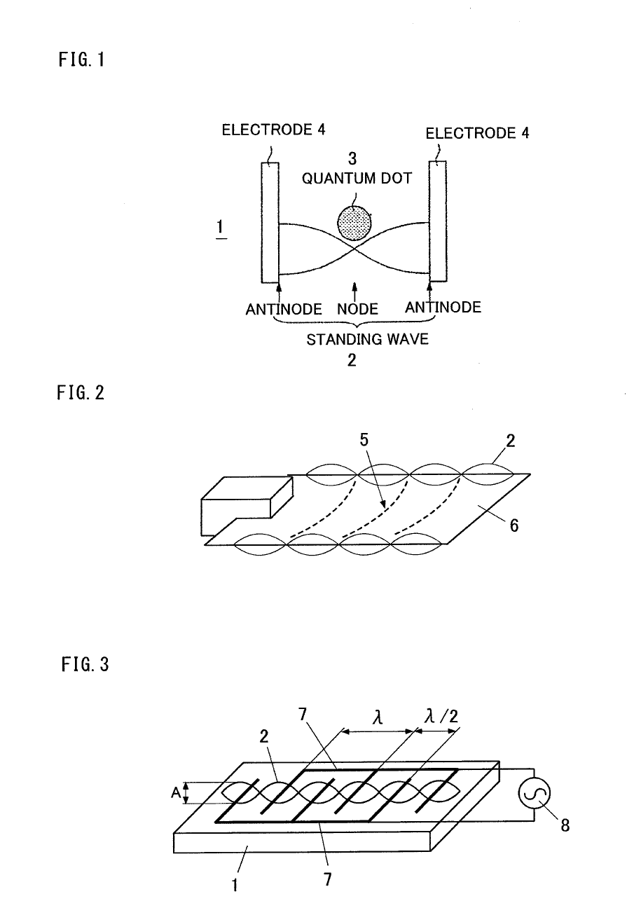

### DESCRIPTION OF THE PREFERRED EMBODIMENT

The following describes preferred embodiments of the present invention with reference to the attached drawings. In the drawings, same reference numerals will be assigned to common parts, and duplicated description will be omitted.

The present inventors have noted surface acoustic waves (SAW) for use as position control means of a minute-structure such as a nanoscale substance.

FIG. 2 explains Chladni figures. Chladni figures refer to a phenomenon where, when a standing wave 2 is generated at a metal plate 6 with powder 5 scattered thereon, the powder 5 will concentrate on positions at nodes of the standing wave to form a figure.

Although such Chladni figures are a macroscale phenomenon, a position distribution of nanoscale substances also may be changed by a standing wave generated using surface acoustic waves if the substance diffuses such that the diffusion length differs between at an antinode and at a node of the standing wave 2. Such a phenomenon can be used as a technique for position controlling of a substance.

The present inventors conducted the following preliminary experiment in which an inter digital transducer (IDT) having adjacent electrodes arranged at an interval of 100 μm was fabricated, on a lithium niobate (LiNbO₃) substrate as a piezoelectric device, and silicon powder with particle sizes ranging from 2 to 3 μm or 20 to 30 μm was scattered thereon. Thereafter, a standing wave of surface acoustic waves was generated on the surface of the substrate, and then, influences on the scattering were observed with an optical microscope.

The present inventors found that behavior of silicon powder changed with a change in frequency of high-frequency waves and a change in intensity of input signals, that is, found that the surface acoustic waves give influence on the substance on the substrate.

The present inventors, however, considered that such results of the preliminary experiment might have various indefinite factors including a variation in shape of fine particles and electrical-charging of silicon powder. There are still further indefinite points including a problem of transmission loss in a high-frequency wave introduction path to the IDT. Therefore, these problems have to be clarified.

In the following description for the present application, the term “piezoelectric substrate” refers to a substrate having a piezoelectric property that produces a deformation under a voltage applied thereto. The term “surface acoustic waves” refer to elastic waves that propagate while concentrating its energy only the vicinity of a surface of an elastic body.

FIG. 3 schematically describes an IDT.

As illustrated in this drawing, when electric field is applied from a high-frequency AC power source 8 to an IDT 7 fabricated on a piezoelectric substrate 1, a piezoelectric effect occurs due to electric field entering into the inside of the piezoelectric substrate 1, thus producing deformation at the vicinity of the surface, and generating surface acoustic waves.

The surface acoustic wave conveyed through the piezoelectric substrate 1 has a sound speed v that is determined by the following expression (1), and the frequency f necessary for generating surface acoustic wave is a function of a length λ between electrodes 7. The expression (1) can be established for the symbol λ in FIG. 3.

v=fλ (1).

Since the parts of the IDT 7 oscillate in phase, a standing wave 2 is generated to have antinodes at electrode parts and nodes at parts between electrodes. In this case, as illustrated in FIG. 3, the length λ corresponds to the wavelength of the above-stated surface acoustic wave generated by the piezoelectric effect, and λ/2 corresponds to a length between an antinode and another antinode of the standing wave 2. In FIG. 3, the reference symbol A denotes twice an amplitude of the standing wave 2.

An “electromechanical coupling coefficient K” represents conversion efficiency between electrostatic energy Ui of a piezoelectric substance and elastic energy Ua. The following expression (2) can be established for the electrostatic energy Ui and the elastic energy Ua:

K=(Ua/Ui)^{0.5} (2).

Herein, K² will be about 0.1(%) for crystal and about 0.75(%) for lithium tantalite with respect to Rayleigh waves, and about 7.6(%) for lithium tantalite with respect to shear horizontal (SH) waves.

An object of the present invention is to control a position of a minute-structure (a nanoscale substance). To this end, the present inventors manufactured a vapor deposition apparatus for a high frequency wave required to downsize the phenomenon, and selected a substance with a diffusion length appropriate to the scale of position controlling for experiment.

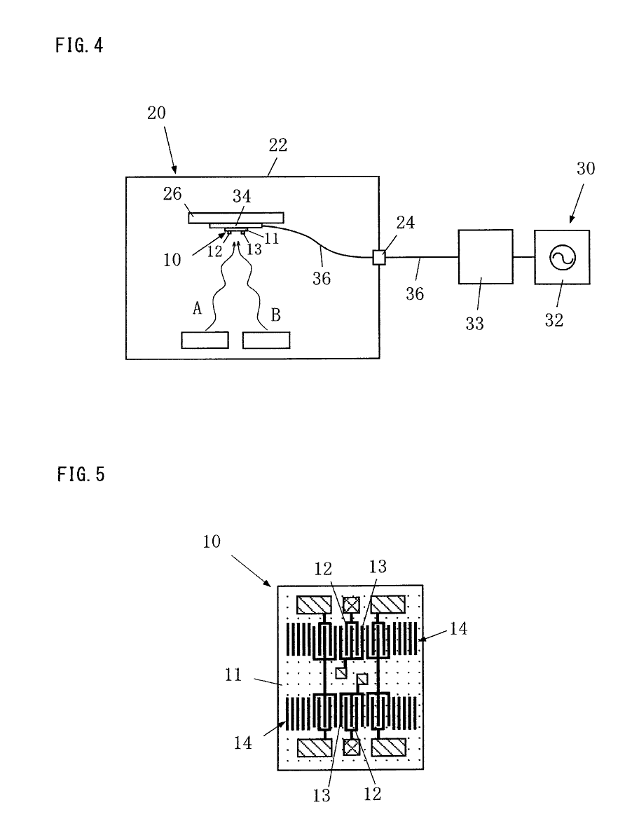

FIG. 4 illustrates the entire configuration of a vapor deposition apparatus for a minute-structure according to the present invention.

In this drawing, the vapor deposition apparatus of the present invention includes a surface acoustic wave device 10, a vacuum vapor deposition device 20, and a high-frequency application device 30.

The surface acoustic wave device 10 includes at least a pair of electrodes 12 and 13 arranged at an interval on a surface of a piezoelectric body 11.

The piezoelectric body 11 is a plate made of a piezoelectric substance such as crystal, LiNbO₃, LiTaO₃ or the like. The electrodes 12 and 13 are preferably comb-shaped opposed electrodes that are positioned at a regular interval. This surface acoustic wave device 10 has a configuration similar to that of a SAW device as one of high-frequency electronic devices.

Accordingly, as the surface acoustic wave device 10, a SAW device can be used. The SAW device as the device 10 has adjacent electrodes that are arranged at an interval of 500 to 900 nm, and has a center frequency of 850 to 900 MHz.

The vacuum vapor deposition device 20 is configured to allow at least two substances of A and B to be vacuum-deposited on a surface of the surface acoustic wave device 10. The substances A and B are fullerene (C₆₀) and silver (Ag) in the example below, but may be other metals or semiconductors.

The vacuum vapor deposition device 20 includes a vacuum chamber 22 that accommodates the surface acoustic wave device 10 therein and is capable of reducing a pressure therein to a predetermined degree of vacuum, and a vacuum connector 24 that lets high-frequency current flow into the vacuum chamber 22.

Vapor deposition by this vacuum vapor deposition device 20 may be any one of heat vapor deposition, sputtering, various types of CVD (Chemical Vapor Deposition) and MBE (Molecular Beam Epitaxy). Preferably, the vacuum vapor deposition device 20 also has an ion sputtering function for cleaning the surface of the surface acoustic wave device 10.

In this illustrated example, the vacuum vapor deposition device 20 is further provided with a substrate heater 26 to heat the substrate (surface acoustic wave device 10) up to a desired temperature.

The high-frequency application device 30 applies a high-frequency voltage to the pair of electrodes 12 and 13 of the surface acoustic wave device 10.

The high-frequency application device 30 includes a high-frequency generator 32, an amplifier 33, a device holder 34, and a coaxial cable 36.

The high-frequency generator 32 generates a high-frequency voltage at a predetermined frequency (e.g., a frequency between 100 MHz to 30 GHz).

The amplifier 33 amplifies the generated high-frequency voltage. The amplifier 33 may be omitted.

The device holder 34 includes an input conductive film (not illustrated) and a grounded conductive film (not illustrated) with impedance matched therebetween, and inputs a high-frequency voltage to the surface acoustic wave device 10.

The coaxial cable 36 includes a center conductor (not illustrated) and shield metal (not illustrated) with impedance matched therebetween, and conveys a high-frequency voltage from the high-frequency generator 32 to the device holder 34 via the vacuum connector 24.

With the above-stated apparatus, in a vapor deposition method for minute-structure of the present invention,

(A) a surface acoustic wave device 10 including at least a pair of electrodes 12 and 13 arranged at an interval on a surface of a piezoelectric body 11 is placed in a vacuum chamber 22, and a pressure of the vacuum chamber 22 is reduced to a predetermined degree of vacuum. The surface acoustic wave device 10 is preferably a SAW device that has adjacent electrodes arranged at an interval of 500 to 900 nm, and has a center frequency of 850 to 900 MHz;

(B) next, a high-frequency voltage is applied between the electrodes 12 and 13 to generate a standing wave of surface acoustic waves on the surface of the surface acoustic wave device 10;

(C) in this state, fullerene is vapor-deposited on the entire surface of the surface acoustic wave device 10. The vapor deposition of fullerene is preferably performed at a substrate temperature from a room temperature to 200° C., at a vapor-deposition rate of 0.6 to 1.7 \acute{Å}/min, and with a vapor-deposition thickness of 30 \acute{Å} to 10 nm; and

(D) next, a minute-structure is vapor-deposited on the fullerene layer at a specific position of the standing wave by the high-frequency voltage.

When a high-frequency voltage at a predetermined frequency is applied between the electrodes 12 and 13 from the high-frequency generator 32 as stated above, the standing wave 2 of surface acoustic waves is generated between the electrodes 12 and 13 in accordance with the frequency.

This standing wave 2 is not limited to a first mode, and the order of the standing wave 2 is determined by the frequency of the high-frequency voltage, the length between the electrodes 12 and 13, and a propagation speed of the surface acoustic waves on the surface (formation face) of the substrate (surface acoustic wave device 10).

Thus, the order of the standing wave 2 can be freely set by adjusting the frequency of the high-frequency voltage that can be easily changed, for example.

For instance, the standing wave 2 of the surface acoustic waves may be sequentially changed to a higher-order mode by sequentially increasing the frequency of the high-frequency voltage, whereby a minute-structure can be vapor-deposited at a position corresponding to a node of the standing wave 2.

When the phases of the surface acoustic waves at the electrodes 12 and 13 are deviated by π (180°), antinodes and nodes of a standing wave are fixed between the electrodes 12 and 13. The formation face at a node is not displaced in the vertical direction, but the displacing amount of the formation face becomes larger at the position that is more separate from the node.

More specifically, each part of the formation face has a different spatial state in the vertical direction due to the standing wave 2. A part with the smallest displacement in the vertical direction (the part corresponding to a node of the standing wave) has a stable spatial state as compared with other parts, and therefore more vaporized material tends to be adhered thereto. On the other hand, a part in an instable spatial state tends to be a position to which vaporized material is not easily adhered.

According to the above-stated apparatus and method of the present invention, the apparatus includes the surface acoustic wave device 10, the vacuum vapor deposition device 20, and the high-frequency application device 30. The surface acoustic wave device 10 including at least the pair of electrodes 12 and 13 arranged at an interval on a surface of the piezoelectric body 11 is placed in the vacuum chamber 22, and a pressure of the vacuum chamber 22 is reduced to a predetermined degree of vacuum. A high-frequency voltage is then applied between the electrodes 12 and 13 to generate a standing wave 2 of surface acoustic waves on the surface of the surface acoustic wave device 10. In this state, a plurality of thin-film layers (e.g., thin-film layers of fullerene, or thin-film layers of a molecule having a size equal to or more than that of fullerene) are formed. As a result, a homogeneous thin-film layer can be formed on the entire surface.

Especially, vapor deposition of fullerene on the entire surface of the surface acoustic wave device 10 in this state allows the diffusion length of fullerene to be increased so as to disperse a cluster of fullerene uniformly, so that a homogeneous fullerene layer can be formed on the entire surface.

Since fullerene (C₆₀) is a functional molecule, and molecules of fullerene are Van der Waals bonded with each other, the large diffusion length can be obtained by several layers of fullerene adsorbed onto the piezoelectric substrate.

Accordingly, a high-frequency voltage is subsequently applied between the electrodes 12 and 13 to generate a standing wave 2 of surface acoustic waves on the surface of the surface acoustic wave device 10, and in this state, a minute-structure (e.g., Ag) is vapor-deposited on the fullerene layer. Thereby, the minute-structure can be vapor-deposited at a specific position (e.g., at the node) of the standing wave by the high-frequency voltage.

As a result, the minute-structure can be formed at a predetermined position while reducing influence of a surface state of the substrate (surface acoustic wave device 10).

The apparatus further includes the device holder 34, that has an input conductive film and a grounded conductive film with impedance matched therebetween and that inputs a high-frequency voltage to the surface acoustic wave device, and the coaxial cable 36 that has a center conductor and shield metal with impedance matched therebetween and that conveys a high-frequency voltage from the high-frequency generator to the device holder via the vacuum connector. Thereby, reflections of high-frequency waves to a power source can be minimized in the device holder 34 and the coaxial cable 36, so that high-frequency waves can be efficiently transmitted to the substrate (surface acoustic wave device 10).

The following describes Examples of the present invention.

### Example 1

### Experimental Method

(1) Vapor Deposition Device for High Frequency

All of the experiments in the present invention were carried out in a vacuum chamber 22 of a high degree of vacuum. For nanoscale vapor deposition during oscillation of surface acoustic waves, high-frequency waves of a predetermined frequency (about 3 GHz at maximum) have to be introduced into the vacuum chamber 22 from the outside. To this end, a vacuum connector 24 for high frequency and a device holder 34 designed and processed for high frequency were used.

FIG. 5 illustrates the circuit configuration of a surface acoustic wave device 10 used in the experiment. In this drawing, the surface acoustic wave device 10 includes a piezoelectric body 11, electrodes 12 and 13, and a reflector 14. The electrodes 12 and 13 are a comb-shaped electrodes (IDT) configured to generate surface acoustic waves between the electrodes 12 and 13. The reflector 14 has a function to promote the oscillation by surface acoustic waves.

In this illustrated example, a pair of surface acoustic wave devices 10 is disposed up and down, so that a surface acoustic wave generated from one of them (e.g., down side) is propagated to the other (e.g., upside) so that they produce resonance.

Such a surface acoustic wave device 10 is commercially available as a SAW device.

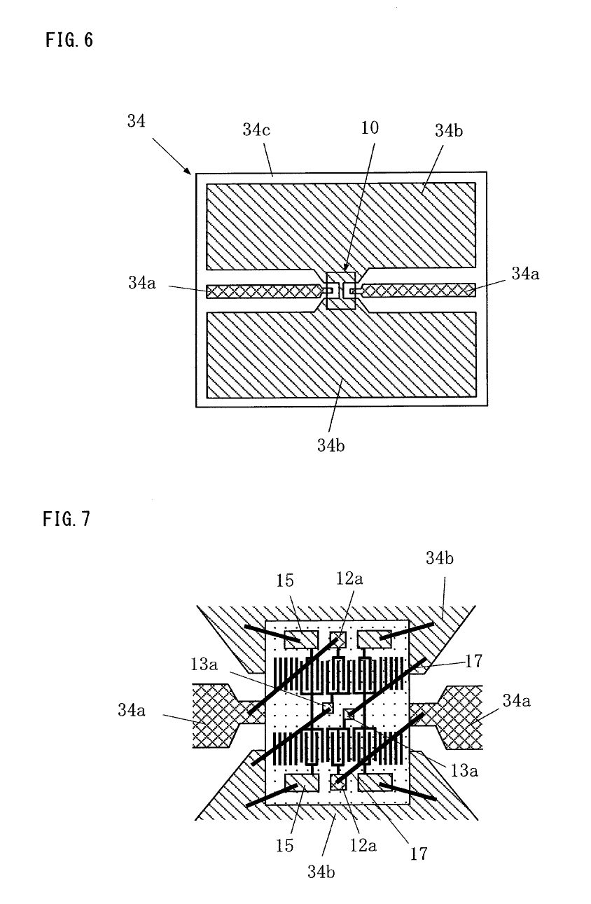

FIG. 6 is a plan view of a device holder 34. In this drawing, the reference numeral 34a denotes an input conductive film, 34b denotes a grounded conductive film, and 34c denotes an insulating substrate (glass). The input conductive film 34a and the grounded conductive film 34b are Cu films with a thickness sufficiently larger than a skin depth by which the used high-frequency waves substantially can penetrate from the surface toward the inside. The input conductive film 34a and the grounded conductive film 34b are plated on the insulating substrate 34c via a NiCr thin film (not illustrated) and an Au thin film (not illustrated). Instead of the Cu film, an Au film may be used.

In general, a skin depth d (a depth where intensity of high-frequency waves is reduced by 1/e times) of a substance is given by the following expression (3):

d=1/(πfμσ)^{0.5} (3),

where f represents frequency [Hz], μ represents magnetic permeability, and σ represents electrical conductivity.

Since copper has magnetic permeability of μ=4π×10⁻⁷[H/m] and electrical conductivity of σ=5.82×10⁷[S/m], in the case of an oscillatory frequency at f=880 MHz, the skin depth d for copper becomes about 2.2 μm. Therefore, the above-mentioned “Cu films with a thickness sufficiently larger than” may have a film thickness of about 20 μm or greater, whereby a leak of high frequency waves can be substantially eliminated.

In the example of the present invention, a Cu film had a thickness of about 80 μm, and the Cu film was plated via a NiCr thin film (about 10 nm thickness) and an Au thin film (about 100 nm thickness). The NiCr thin film and the Au thin film were disposed because a Cu film directly plated to an insulating substrate (glass) is easily peeled, and therefore the NiCr thin film that can be plated to an insulating substrate (glass), and the Au thin film to which copper plating is possible were disposed as an intermediate layer.

The size (about 20 mm in width, about 25 mm in length) of the device holder 34, and the thickness of a Cu film (about 80 μm) were set such that impedance of the input conductive film 34a and the grounded conductive film 34b was matched with the power source side and the substrate side.

FIG. 7 is a connecting diagram between the device holder 34 and the surface acoustic wave device 10. In this drawing, the reference numeral 12a denotes an input terminal of the electrode 12, 13a denotes an input terminal of the electrode 13, 15 denotes a ground terminal, and 17 (thick line) denotes a bonding wire (Au wire).

In this example, electrical connection between the input terminal 12a and the input conductive film 34a, between the input terminal 13a and the grounded conductive film 34b, and between the ground terminal 15 and the grounded conductive film 34b are established via the bonding wires 17.

Further, the center conductor of the above-stated coaxial cable 36 is electrically connected with one side (e.g., right side) of the input conductive film 34a, and the shield metal of the coaxial cable 36 is electrically connected with the grounded conductive film 34b.

With this configuration, in the device holder 34 and the coaxial cable 36, a leak of high-frequency waves and reflections to the power source can be significantly reduced, so that high-frequency waves can be efficiently transmitted to the substrate (surface acoustic wave device 10).

Further in the present invention, a spectrum analyzer (not illustrated) is provided for improved detection means in such a manner that the spectrum analyzer is electrically connected with the other side (e.g. left side) of the input conductive film 34a and the grounded conductive film 34b via a coaxial cable so as to detect surface acoustic waves generated in the surface acoustic wave device 10.

(2) Estimation of Diffusion Length

In order to generate surface acoustic waves using an IDT and observe a positional change of a minute-structure (nanoscale substance), a diffusion length of an absorption substance on a piezoelectric substrate has to be about ⅓ of a length between the electrodes of the IDT. It is known that fullerene molecules are Van der Waals bonded with each other, and conceivably, a large diffusion length can be obtained by adsorbing one to three layers of fullerene on the piezoelectric substrate. Then, fullerene was vapor-deposited on a LiNbO₃ substrate as the piezoelectric substrate, and a diffusion length on the surface was estimated. At this time, a substrate temperature and a vapor-depoition rate were changed as parameters.

### Example 2

(3) Experiment by Oscillation of a SAW Device

An experiment was carried out using a surface acoustic wave device (hereinafter called a “SAW device”) sold as a filter using surface acoustic waves and provided with an IDT having comb-shaped electrodes that are arranged at an interval of about 1 μm. Since a SAW device is used as a frequency filter that produces resonance of the IDT at a natural frequency, a stable standing wave of surface acoustic waves can be generated between the electrodes. The experiment used a SAW device (produced by Murata Manufacturing Co., Ltd.) including a crystal substrate, and a SAW device (produced by Hitachi Media Electronics Co., Ltd.) including a lithium tantalite substrate that has an electromechanical coupling coefficient larger than that of the crystal substrate. The SAW devices were heated by energization-heating that uses tungsten wires, and a temperature thereof was measured by an alumel-chromel thermocouple attached to the device holder 34.

### Experimental Result

### <Estimation of Diffusion Length>

An average length between clusters was obtained based on an SEM image for the observation after vapor deposition. Table 1 shows a result thereof. On the Basis of this experimental result, an apparent diffusion length was estimated to range from about 100 to 200 nm, and absorption energy with the substrate was estimated to be about 0.06 eV by taking into account temperature change between clusters. Therefore, it was found that a distance between adjacent electrodes of approximately twice the diffusion length enables the observation of the influences caused by surface acoustic waves.

TABLE 1

| VAPOR- | SUBSTRATE TEMPERATURE | |
|---|---|---|
| DEPOSITION RATE | 50° C. | 200° C. |
| ~1 Å/min | 127.5 nm | 213.4 nm |
| 2~3 Å/min | | 124.5 nm |

### Example 3

### <Experiment Using a SAW Device of Crystal Substrate>

Fullerene was vacuum-deposited while exciting a SAW device that has crystal substrate having adjacent electrodes arranged at an interval of about 900 nm and that has a center frequency of 868 MHz.

High frequency waves were output from the high-frequency generator 32 (RF oscillator) at 17 dBm, were amplified to 30 dBm (101.3 times) by the amplifier 33 (power amplifier), and were then applied to the comb-shaped electrodes 12 and 13 of the IDT.

Since the diameter of fullerene is about 1 nm, in order to make a comparison with absorption energy, energy of elastic waves per second in a unit area (1 nano square meter) of the comb-shaped electrode portion was calculated on the basis of an output value from the RF oscillator. As a result, the calculated energy was 2.52×10⁴ [eV/nm²]. Therefore, it can be expected that in the case where an average staying time of fullerene molecules on the substrate is about 10⁻⁶ [sec], the energy of elastic waves becomes substantially equal to the absorption energy, and an absorption substance can be easily diffused by oscillation of the substrate.

Fullerene was deposited under the condition that can expect the diffusion length of 200 nm or greater, i.e., the condition that the substrate temperature is 200° C., the vapor-deposition rate is 0.6 to 0.8 \acute{Å}/min, and the vapor-deposition thickness is 30 \acute{Å}. The surface acoustic wave was received by the antenna installed in the deposition chamber, and was detected by the spectrum analyzer to confirm the surface acoustic wave oscillation.

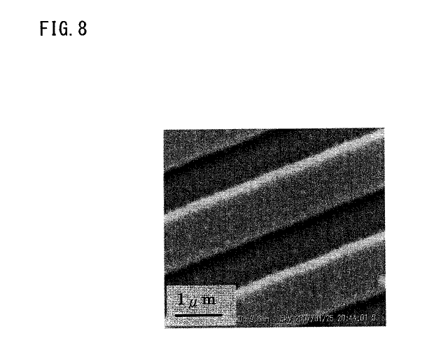

FIG. 8 illustrates an SEM image of the substrate surface obtained from this experiment.

It was found that clusters of fullerene on the substrate of FIG. 8 were substantially uniformly distributed, and further, a distance between the clusters was much shorter than that observed on a LiNbO₃ substrate. Conceivably, this resulted from heterogeneous nucleation due to dirt or the like on the substrate because the final surface treatment of the crystal substrate was uncertain. Then, the present inventors considered that it was difficult to decide influences by surface acoustic waves on the basis of this SEM image, and decided to use a SAW device using a Li-based substrate as a substrate with a larger electromechanical coupling coefficient. Further, since transmission loss of high-frequency waves appeared to occur in the deposition chamber, the introduction path was improved again.

After such improvement, the configuration of the device holder 34 shown in FIG. 6 and the bonding wires shown in FIG. 7 were obtained.

### Example 4

### <Experiment Using a SAW Device of Lithium Tantalite (LiTaO₃) Substrate>

In this experiment, fullerene was vapor-deposited while exciting a LiTaO₃-substrate SAW device that has the adjacent electrodes arranged at an interval of about 500 nm and that has a center frequency of 881 MHz.

At the beginning, the experiment was tried under the conditions that the high frequency output was 17 dBm, and the substrate temperature was 200° C. However, problems such as damage to the IDT have developed, and therefore, another experiment was carried out under the conditions that the high frequency output was 7 dBm ( 1/10), and the substrate temperature was a room temperature.

Similarly to the case of the crystal device, energy of the elastic waves per unit area was calculated, and the result was 1.34×10⁵ [eV/nm²] per second. Although the result was slightly inferior to the experiment with crystal, it was expected that the improved high-frequency introduction path would enable waves to be transmitted via the coaxial cable very near to the sample, so that large amplitude could be given.

So far, observation was performed with a fullerene vapor-deposition rate of about 1.7 \acute{Å}/min while changing the vapor-deposition amount. Herein, when the vapor-deposition amount was 50 \acute{Å}, any influence on the distribution of clusters was not observed, and another experiment was carried out while increasing the vapor-deposition amount and the input power of high-frequency waves. As stated above, in order to securely detect the surface acoustic wave oscillation, oscillation was transmitted using a coaxial cable from the output side of the SAW device to be detected by the spectrum analyzer.

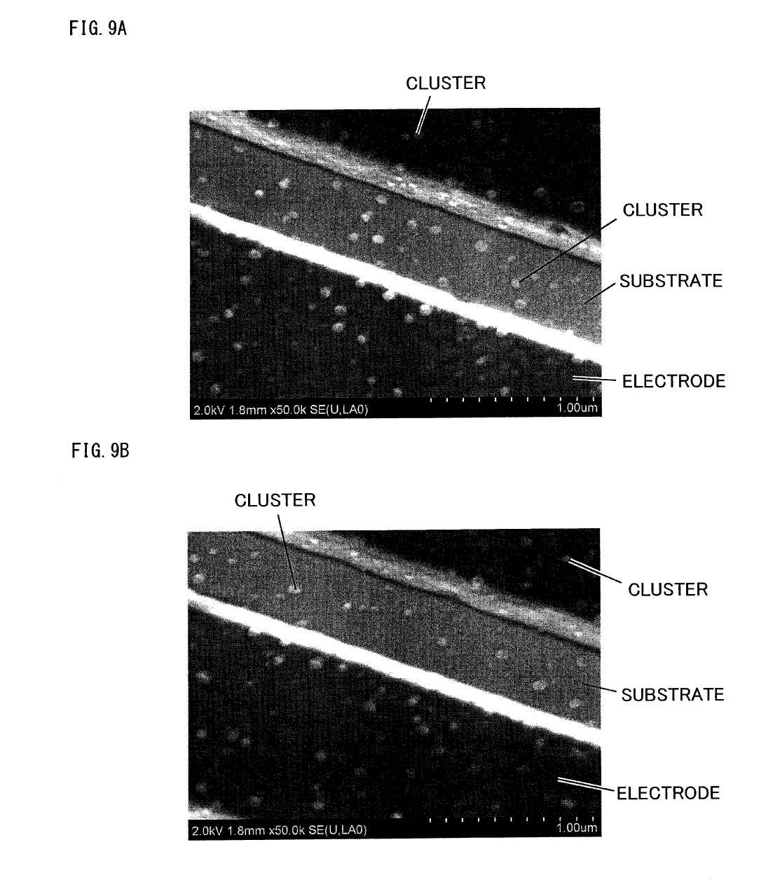

FIGS. 9A and 9B illustrate SEM images of a substrate surface when fullerene was vapor deposited on a substrate while applying a high-frequency voltage to the substrate. FIG. 9A and FIG. 9B illustrate the SEM images at different areas on the substrate.

This vapor-deposition was carried out under the condition that the substrate temperature was a room temperature, the vapor-deposition rate was 1.7 \acute{Å}/min, the vapor-deposition amount of fullerene film was 5 nm, and the high frequency was applied at 7 dBm.

In FIG. 9A and FIG. 9B, clusters of fullerene were substantially uniformly distributed on the entire face of the substrate and the electrodes, so that it was found that a homogeneous fullerene layer was formed on the entire surface.

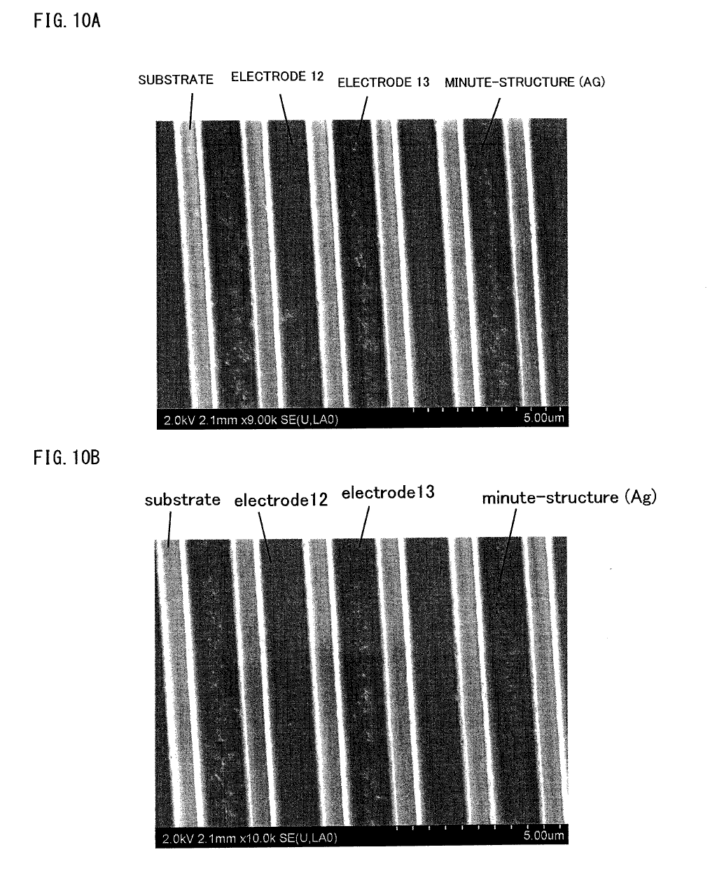

FIGS. 10A and 10B illustrate SEM images of a substrate surface that was obtained as follows. The substrate illustrated in FIG. 9A and FIG. 9B was used, and a high-frequency voltage was applied between electrodes so as to generate a standing wave of surface acoustic waves on the surface of a surface acoustic wave device. In this state, Ag was deposited on the fullerene layer, obtaining the SEM images. FIG. 10A and FIG. 10B illustrate the SEM images at different areas on the substrate.

The vapor deposition of a minute-structure was carried out under the condition that the substrate temperature was a room temperature, the vapor-deposition rate was 1.7 \acute{Å}/min, the fullerene film thickness was 5 nm, the Ag film thickness was 2 nm, and the high frequency was applied at 7 dBm.

In FIG. 10A and FIG. 10B, a minute-structure of Ag was deposited only at a specific position (a node part of the input electrode 12) of the standing wave generated by the high-frequency voltage, and it was found that a minute-structure was able to be formed at a predetermined position while reducing interaction with the surface of the substrate (the surface acoustic wave device 10) and the electrode surface.

According to the above-stated present invention, high-frequency waves generated at the high-frequency generator 32 are input to the vacuum chamber 22 via the coaxial cable 36 and the vacuum connector 24, and further reach the surface acoustic wave device 10 via a waveguide (device holder 34), so that a standing wave 2 of surface acoustic waves is generated on the surface acoustic wave device 10. The generated standing wave 2 is detected by a spectrum analyzer.

In the state of generating the standing wave 2, a second layer is vacuum-deposited. Large molecules such as fullerene may be used for the first layer, and a desired material may be used for the second layer.

On the substrate, the standing wave can form a spot having high surface energy where fine particles are concentrated, so that a nanostructure can be formed.

The above described embodiments are to be considered as illustrative and not restrictive. The scope of the present invention is indicated by the appended claims. The scope of the present invention embraces all changes which stay within the meaning and range of equivalency of the claims.

1. A vapor deposition apparatus for a minute-structure, comprising:
a surface acoustic wave device that includes at least a pair of electrodes arranged at an interval on a surface of a piezoelectric body;
a vacuum vapor deposition device that vacuum-deposits at least two substances on a surface of the surface acoustic wave device; and
a high-frequency application device that applies a high-frequency voltage between the electrodes of the surface acoustic wave device,
wherein in a state where a standing wave of surface acoustic waves is generated on the surface of the surface acoustic wave device by applying the high-frequency voltage, a plurality of thin film layers are formed, and a minute-structure is vapor-deposited at a specific position of the standing wave.

2. The vapor deposition apparatus for a minute-structure according to claim 1,
wherein a fullerene layer is vapor-deposited on an entire surface of the surface acoustic wave device to form the plurality of thin film layers, and then, the minute-structure is vapor-deposited at the specific position of the standing wave.

3. The vapor deposition apparatus for a minute-structure according to claim 1,
wherein the vacuum vapor deposition device includes a vacuum chamber that accommodates the surface acoustic wave device therein and reduces a pressure therein to a predetermined degree of vacuum, and a vacuum connector that introduces high-frequency current into the vacuum chamber, and
the high-frequency application device includes:
a high-frequency generator that generates a high-frequency voltage at a predetermined frequency;
a device holder that includes an input conductive film and a grounded conductive film with impedance matched therebetween, and that inputs a high-frequency voltage to the surface acoustic wave device; and
a coaxial cable that includes a center conductor and shield metal with impedance matched therebetween, and that conveys a high-frequency voltage from the high-frequency generator to the device holder via the vacuum connector.

4. The vapor deposition apparatus for a minute-structure according to claim 3,
wherein the input conductive film and the grounded conductive film are plated on an insulating substrate via a NiCr thin film and an Au thin film,
and each of the input conductive film and the grounded conductive film is a Cu film with a thickness sufficiently larger than a skin depth by which the high frequency current can penetrate from a surface to an inside thereof.

5. A method for vapor-depositing a minute-structure, comprising the steps of:
placing a surface acoustic wave device in a vacuum chamber, and reducing a pressure of the vacuum chamber to a predetermined degree of vacuum, the surface acoustic wave device including at least a pair of electrodes arranged at an interval on a surface of a piezoelectric body;
applying a high-frequency voltage between the electrodes to generate a standing wave of surface acoustic waves on a surface of the surface acoustic wave device; and
in this state, forming a plurality of thin film layers on the surface acoustic wave device, and vapor-depositing a minute-structure at a specific position of the standing wave.

6. The method for vapor-depositing a minute-structure according to claim 5,
wherein a fullerene layer is vapor-deposited on an entire surface of the surface acoustic wave device to form the plurality of thin film layers, and then, the minute-structure is vapor-deposited at the specific position of the standing wave.

7. The method for vapor-depositing a minute-structure according to claim 6,
wherein the fullerene layer is vapor-deposited at a substrate temperature ranging from a room temperature to 200° C., at a vapor-deposition rate of 0.6 to 1.7 \acute{Å}/min to obtain a vapor-deposition thickness of 30 \acute{Å} to 10 nm.

8. The method for vapor-depositing a minute-structure according to claim 5,
wherein the surface acoustic wave device is a SAW device that has the adjacent electrodes arranged at an interval ranging from 500 to 900 nm, and has a center frequency ranging from 850 to 900 MHz.

9. The method for vapor-depositing a minute-structure according to claim 5,
wherein the minute-structure is vapor-deposited at a position corresponding to a node of the standing wave while sequentially changing the standing wave of surface acoustic waves to a higher-order mode by sequentially increasing a frequency of the high-frequency voltage.
